(19) United States
(12) Patent Application Publication
(10) Pub. No.: US 2007/0147458 A1
(43) Pub. Date: Jun. 28, 2007

(54) Cavity and packaging designs for arrays of vertical cavity surface emitting lasers with or without extended cavities

(75) Inventors: Jason P. Watson, San Jose, CA (US); Andrei V. Shchegrov, Campbell, CA (US); Aram Mooradian, Kentfield, CA (US); Kenneth D. Scholz, Palo Alto, CA (US); William R. Hitchens, Mountain View, CA (US); Brad Cantos, San Francisco, CA (US); John Green, Scotts Valley, CA (US)

Correspondence Address: COOLEY GODWARD KRONISH LLP, 3000 EL CAMINO REAL, 5 PALO ALTO SQUARE, PALO ALTO, CA, 94306, US

(73) Assignee: Novalux, Inc., Sunnyvale, CA (US)

(21) Appl. No.: 11/450,044

(22) Filed: Jun. 9, 2006

Related U.S. Application Data
(60) Provisional application No. 60/689,582, filed on Jun. 10, 2005.

(51) Int. Cl. H01S 5/00

(52) U.S. Cl. 372/50.124; 372/50.12

(57) ABSTRACT

Arrays of surface emitting lasers are disclosed. A top contact plate is patterned with apertures and used to form an electrical connection to a top surface of a laser die. The top contact plate reduces electrical resistance and improves current uniformity compared with conventional contacts formed by plating.

### CROSS-REFERENCE TO RELATED APPLICATIONS

This application claims the benefit of provisional application 60/689,582, filed on Jun. 10, 2005, the contents of which are hereby incorporated by reference.

### FIELD OF THE INVENTION

The present invention is generally related to surface emitting semiconductor lasers. More particularly, the present invention is related to packaging of high-power surface emitting semiconductor lasers.

### BACKGROUND OF THE INVENTION

Vertical cavity surface emitting lasers (VCSELs) are common in low power applications. For example, a VCSEL may include a quantum well semiconductor active region sandwiched between distributed Bragg reflectors (DBRs) to provide optical feedback. Additionally, vertical cavity surface emitting gain elements can be utilized in an extended cavity configuration in which an additional reflective element, spaced apart from the semiconductor gain element, is used to provide additional optical feedback. A vertical cavity surface emitting laser gain element utilized in an extended cavity configuration is commonly known as a vertical extended cavity surface emitting laser (VECSEL). VECSELs are thus a class of vertical cavity surface emitting lasers in which an additional reflector is used to form an extended cavity. VECSELs have been disclosed in patents by Mooradian (“High power laser devices,” U.S. Pat. No. 6,243,407; “Efficiency high power laser device,” U.S. Pat. No. 6,404,797; “High power laser,” U.S. Pat. No. 6,614,827; “Coupled cavity high power semiconductor laser,” U.S. Pat. No. 6,778,582), the contents of each of which are hereby incorporated by reference.

An advantage of VECSELs is that they may be designed to have a comparatively large diameter, such as a diameter of between 50 to 200 microns, which results in both higher power output and improved efficiency due to improved gain utilization. FIG. 1 illustrates a VECSEL disclosed in U.S. Pat. No. 6,614,827, which is commonly owned by the assignee of the present invention. As described in more detail in U.S. Pat. No. 6,614,827, a semiconductor substrate 20, has a semiconductor quantum-well gain region 22. A first reflector 26, such as a p-type Bragg reflector, is formed on the quantum-well gain region 22. A second external reflector 30 is spaced apart from the first reflector 26. The distance, L, between the first and second reflectors 26, 30 and their respective curvatures define a cavity mode. An annular electrical contact 28 causes current 38 to flow between annular contact 28 and a circular contact 40 on an opposite face of the substrate 20. The resulting current flow 38 is, to a first approximation, conical in shape with the base 39A of the cone being at the annular contact 28 and the peak of the cone 39B being near contact 40. The flow in the peak of cone 39B is generally circular in cross section and energizes a first substantially cylindrical volume 44 of the gain region 22, the first volume 44 being of a cross-sectional diameter D₁. In turn, the excited gain region 22 of diameter D₁ generates stimulated and spontaneous emission, represented by arrows 48, which travels in a direction transverse to the propagation of the cavity laser beam. A portion of the transverse energy 48 is absorbed in a second annular volume 46 surrounding the first pumped volume. This absorbed energy serves to pump a second volume 46. The energy pumped into the second region D₂ can be extracted in the orthogonal direction by designing the VECSEL to have a mode waist equal to D₂ at the gain medium. Thus, a large diameter VECSEL can be designed to efficiently recycle transverse energy 48, resulting in high efficiency. A VECSEL structure is also suitable for intracavity frequency doubling by including an appropriate intracavity frequency doubling crystal 58.

Research continues to be conducted to optimize the power output of individual aperture VCSELs and VECSELs. Inevitably, however, increasing the power output of single aperture VCSELs and VECSELs becomes difficult. One alternative to single aperture scaling is to create arrays of devices. This approach allows higher powers to be reached by combining the output of lower power devices. These arrays of lower power devices are generally easier to build than a single emitter of equivalent power. However, there are several issues that present themselves in array construction. In particular, current handling and die-attach are issues that must be solved in order to make an arrayed device work as well as a single emitter.

Historically, there has been comparatively little commercial development of VCSEL or VECSEL arrays for high power applications. This is in part due to the fact that high power arrays of edge-emitting lasers are typically more efficient and simpler to construct than VCSEL arrays. As a result, arrays of edge-emitting lasers are often used as pump sources. Arrays of low power VCSELs have been used in some comparatively low power optical switch and interconnect schemes. In these latter applications,,the low power levels minimize the problems of current handling and die attach, and coherent locking is not required.

However, VCSEL and VECSEL arrays have several potential advantages. There are some new applications which could be well served by the properties of high-power VCSEL and VECSEL arrays. In particular, highly efficient, diode-pumped solid-state (DPSS) lasers typically have very narrow pumping transitions, which impose stringent wavelength requirements on the pump diodes. Due to the nature of their construction, VCSELs emit at a single, epitaxially defined wavelength, and do not typically suffer from longitudinal mode-hops. Edge emitting laser arrays do not posses these attributes, and so must be wavelength-stabilized in some other fashion. This typically involves additional optical elements, which complicate the design of the laser. In addition to the wavelength selectivity benefits, high power VCSELs typically posses circular emitting areas that are much larger than the typical mode size of an edge emitting laser. This means that VCSELs are less prone to optical damage and do not require asymmetric collimation optics, as do edge-emitting lasers. In short, while the issues associated with packaging high power VCSEL or VECSEL arrays have historically limited their use and development, new applications have arrived which would benefit from such devices.

Current handling in a VCSEL or VECSEL is a unique challenge, in that current flow and light output vary collinearly. This means that non-uniformities in current injection across an array of VCSELs or VECSELs will cause variations in light output. (power and perhaps also wavelength) across the array. However, it is difficult to achieve uniform current injection in a conventional array design. In a typical conventional array design, the larger size of the semiconductor die means that the current path can be more than ten times longer than in a single emitter. This imposes constraints on the allowed resistance of the electrical traces. If the resistance is too large, current injection will not be sufficiently uniform across the array.

An illustrative example of some of the problems associated with achieving uniform current injection for a one dimensional (“ID”) VCSEL OR VECSEL array is shown in FIG. 2. FIG. 2 illustrates a calculation of trace voltage drop per emitter in a linear array caused by trace resistance for three different trace metal thicknesses. In the case of FIG. 2, the array is comprised of 20 elements spaced evenly along a 5 mm strip having a width of 500 microns. The metallization, and therefore the resistance, is assumed to be uniform for both sides of the device. The drive current is taken to be 600 mA per emitter, typical for VCSELs with active areas ˜100 microns in diameter. The example in FIG. 2 consists of an array of emitters connected in parallel by a film of gold. That is, the emitters are formed on a common die with a thin film of gold used to form traces to a top side of each emitter of the array. As a result the total trace metal path length to each device depends upon its position on the common die. The thickness of the trace metal corresponds to two microns in plot 205, five microns in plot 210, and ten microns in plot 215. The voltage drop in the trace metal increases farther out from the center of the die, due to the increased path length from the center. The trace voltage drop decreases and becomes more uniform as the thickness of the trace metal increases. The thickness of the film is constrained in conventional evaporation and plating processes to be no more than the thickness of a photoresist layer, which in typical photolithography techniques corresponds to a maximum trace metal thickness of approximately ten microns. Resistance also decreases inversely with the width of the array. However, the width of the array is practically constrained by the requirement that many arrays must fit onto a wafer for a practical design, and also by the realization that such an array should be scalable to a two-dimensional (“2D”) system, and thus the width of the array should be similar, if not equal, to the spacing between elements. Additionally, the constraint for scaling to a 2D array means that the current injection must be from either end of the array, as the other sides are presumed to be filled with neighboring arrays.

Note that even for the thickest metal layers in plot 215, the voltage difference between emitters at the edge of the array and emitters in the center (as defined by the difference in voltage drop due to trace resistance) is 60 mV. This would in turn lead to differences in drive current and dissipated power of 5-10% between emitters. The resulting differences in emitter temperature create problems for wavelength uniformity and power uniformity, both of which are critical for newer applications.

A trace metal thickness of about ten microns appears to be close to the limit that can be practically achieved with conventional semiconductor processing techniques based on evaporation or plating. In particular, since at least one side of the chip must be patterned to allow light to escape, the thickness of the patterned metal will be constrained by the thickness of current photoresist layers (which is approximately 10 microns, as mentioned above). While improvements in technology may increase these limits, the economics of utilizing large-scale layers of thick, deposited metals will continue to be a problem.

Therefore, in light of the above-described problems embodiments of the present invention were developed.

### SUMMARY OF THE INVENTION

An array of surface emitting lasers includes a laser die having an array of vertical cavity surface emitting laser gain elements. The laser die has an array of surface emitting apertures disposed on a top surface of the laser. One set of electrical connections to the laser die is made via an electrical conductive top contact plate mounted in electrical contact with the top surface of the laser die. The electrically conductive top contact plate is formed from at least one electrically conductive sheet patterned to allow light from the surface emitting apertures to pass through the top-contact plate.

### BRIEF DESCRIPTION OF THE FIGURES

The invention is more fully appreciated in connection with the following detailed description taken in conjunction with the accompanying drawings, in which:

FIG. 1 illustrates a vertical extended cavity surface emitting laser in accordance with the prior art;

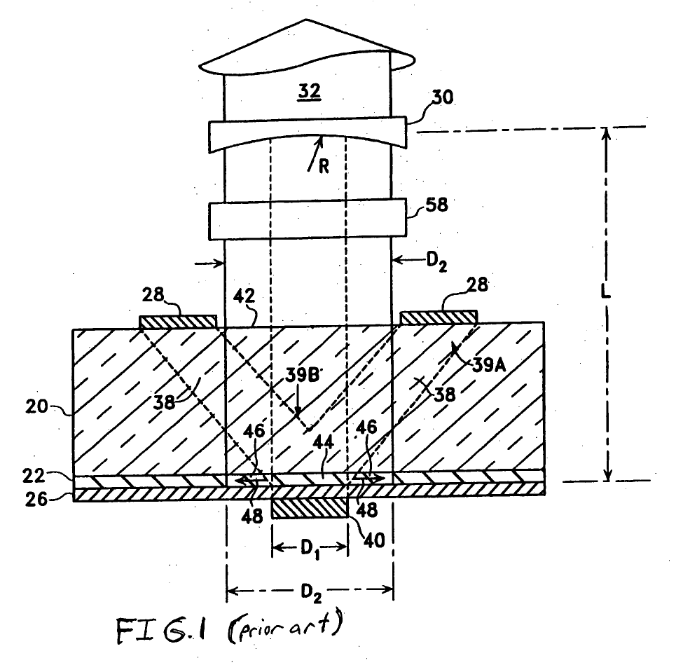

FIG. 2 illustrates a calculation of a voltage drop across an array of surface emitting lasers caused by the resistance of electrical traces;

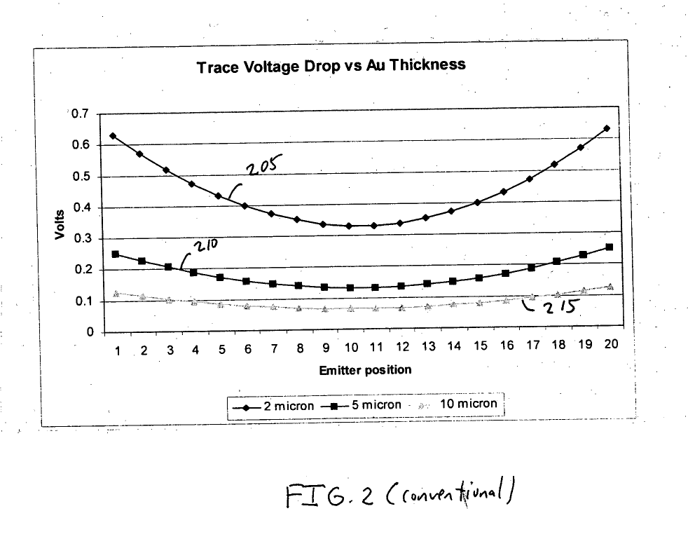

FIG. 3 is an exploded perspective view of a laser array apparatus in accordance with one embodiment of the present invention;

FIG. 4 is a cross sectional view of the laser array apparatus of FIG. 3; and

FIG. 5 illustrates packaging a laser die with a top contact plate in accordance with one embodiment of the present invention.

Like reference numerals refer to corresponding parts throughout the several views of the drawings.

### DETAILED DESCRIPTION OF THE INVENTION

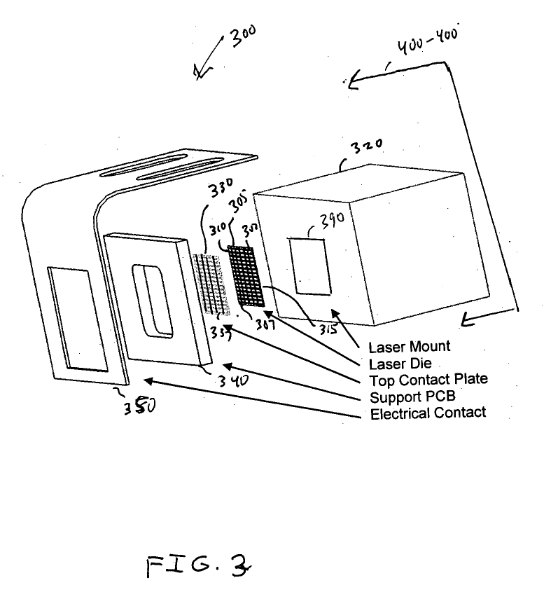

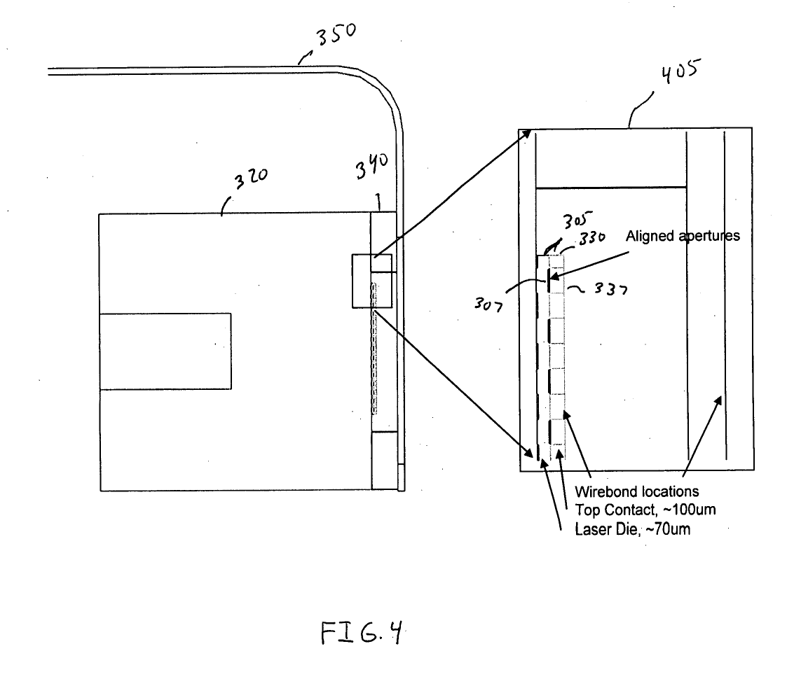

FIG. 3 is an exploded perspective view of a laser array apparatus 300 in accordance with one embodiment of the present invention. FIG. 4 is a cross section along line 400-400 of FIG. 3. Referring to FIG. 3, a laser die 305 may comprise suitable p-n junction diodes having gain regions and one or more distributed Bragg reflectors (DBRs) to serve as the basis for a VCSEL or a VECSEL. As one example, laser die 305 may include a quantum well gain region (not shown) and one or more distributed Bragg reflectors (DBRs) (not shown) similar to that described in U.S. Pat. Nos. 6,243,407, 6,404,797, 6,614,827 or 6,778,582. An array of surface emitting laser elements is fabricated onto the laser die 305, with each surface emitting laser element having an emitting surface 307 disposed along a top surface 310 of laser die 305. In a VECSEL embodiment each individual surface emitting laser element is preferably a comparatively large diameter emitter, such as an emitter having a diameter between about fifty microns and 200 microns. In particular, emitters having a diameter between about fifty microns and 200 microns improves power output and also increases manufacturability.

One set of electrical connections of a first polarity is made between the backside 315 of the laser die 305 and the laser mount 320 to which the laser die is mounted. In one embodiment, laser mount 320 acts as the primary heat sink for laser die 305. The laser mount 320 may provide a single electrical contact to the entire die. More generally, however, the laser mount 320 may include an electrically patterned submount 390 for forming separate electrical connections to different portions along the surface of the backside 315 of laser die 305 bonded to submount 390. Another set of electrical connections of a second polarity is made to top surface 310 of laser die 305 via an electrically conductive top contact plate 330. For example, electrically conductive top contact plate 330 may be electrically connected to individual annular electrical contacts (not shown in FIG. 3) formed on top surface 310 for each individual laser gain element of the laser array.

Top contact plate 330 is patterned to have apertures 337 to permit light from apertures 307 on the laser die 305 to be transmitted through top contact plate 330. A printed circuit board (PCB) 340 may be included as a support member and may also include electrical interconnects (not shown) to establish an electrical connection of a second polarity between top contact plate 330 and an electrical contact member 350.

The thickness of top contact plate 330 is preferably sufficiently thick in light of its effective electrical conductivity to reduce electrical resistance to each individual emitter. In one embodiment, the thickness and conductivity of top contact plate 330 is selected to achieve a current uniformity of at least about 1% across laser die 305. In one embodiment the top contact plate 330 has a thickness comparable to at least about one-half the diameter of the apertures 337 and 307 to improve manufacturability. Desirable ranges of apertures 307 are typically between about fifty to two-hundred microns for high power VECSELs with 100 microns being an exemplary VECSEL diameter. For example top contact plate 330 may have a thickness of about fifty to one-hundred microns to improve electrical conductivity and manufacturability. A thicker top contact plate 330, such as a top contact plate between about one-hundred microns to two-hundred microns, may be desirable for some applications but also makes it more difficult to pattern apertures 337. By way of comparison, conventional plating techniques for plating traces to top surface 310 limit metal thicknesses to about ten microns and result in a corresponding current non-uniformity of 5-10% in many applications. Thus, compared with conventional techniques to form electrical connections to top surface 310 top contact plate 330 permits improvements on the order of a factor of five-to-ten in terms of metal thickness and conductance, such that current uniformity may be improved by a factor of five-to-ten. However, note that in some applications even a factor of two improvement in conductivity and current uniformity over conventional plating techniques may be sufficient to provide a significant benefit.

The top contact plate 330 is preferably formed from a highly electrically conductive material, such as a metal, but it may also be desirable to select the material structure of top contact plate 330 based on its expansion match to the laser die and manufacturing considerations. Additionally, the top contact plate 330 may comprise a stack of plates or a plate coated with one or more layers of materials to achieve a desired combination of electrical conductivity, stiffness, and rate of thermal expansion. Typical, highly conductive metals have thermal expansion rates of 15-25 ppm/K, while typical semiconductor laser dies have thermal expansion rates of ˜5 ppm/K. The contact plate may also be a composite of metals, insulators, or alloys, formed in such a way to provide both high electrical conductivity and a thermal expansion match to the laser die.

In one embodiment top contact plate 330 has a thickness and thermal conductivity selected such that top contact plate 330 functions as an auxiliary heat sink.. That is, top contact plate 330 plate is both electrically and thermally coupled to top surface 310 of laser die 305 to assist in cooling the laser die. In this case the laser die 305 is preferably configured to minimize thermal barriers to heat flow to top contact plate 330. In some implementations of laser die 305, the laser die will have active p-n junction regions disposed proximate backside 315 and a semiconductor substrate disposed along top surface 310 (what is sometimes known as a “junction down” implementation, since the heat producing active regions are mounted in close proximity to mount 320). The laser die 305 may be processed to reduce the thickness of substrate layers or fabricated layers that act as thermal barriers to heat flow to top contact plate 330. For example, top contact plate 330 may be mounted as close to the active region of the laser die as practical to improve the flow of heat to top contact plate 330. The thermal conductivity of common semiconductor materials, e.g. GaAs, is much less than that of metals, e.g. copper, and so a significant amount of semiconductor material will serve to block the transfer of heat to the top contact. In order for top contact plate 330 to function as an auxiliary heat sink, it is desirable that top contact plate 330 conduct a significant amount of heat, such as at least 10% of the heat generated by laser die 305. For such a case, the laser die 305 is heat sunk to both the laser mount 320 and also to top contact plate 330.

Referring to inset 405 of FIG. 4, which shows a detailed portion of laser array apparatus 300, the top contact plate 330 has apertures 337 patterned to match the pattern of emitting areas 307 on the laser die 305. In an exemplary embodiment the laser die 305 has a thickness of seventy microns and the top contact plate 330 has a thickness of one-hundred microns. The top contact plate 330 is aligned with the laser die 305 and attached in a manner that allows current to flow between the top contact plate 330 and the laser die 305. The top contact plate 330 and laser die 305 may have additional patterning that allows for simplified or automatic alignment, such as fiducial marks (not shown). In the simplest case of manual alignment, the apertures 307 and 337 on both parts are circular with the top contact plate 330 having apertures 337 of a slightly larger diameter. This arrangement allows for simple, manual alignment by observing the concentricity of apertures 307 and apertures 337. Manual alignment processes can easily be used to achieve an alignment of apertures 337 with respect to apertures 307 that is better than twenty-five microns by those skilled in the art. Note also that with sufficient manufacturing volumes that a fine optical alignment may be partially or fully automated. The apertures 337 and alignment features in the top contact plate 330 may be formed by any number of methods, including photo-etching, mechanical drilling, or laser-drilling. The laser die 305 and top contact plate 330 are attached to mount 320, which serves as the second electrical contact. The mount 320 also serves to remove and spread waste heat from the array. The mount 320 may be made of pure metal, such as copper, a composite, such as copper /diamond, or other, more complicated structures. These latter structures attempt to add additional functionality to the mount 320, such as cooling or improved heat conduction. Such features may also be added to the top contact plate 330 as well, in a similar fashion.

The top contact plate 330 can be bonded to the laser die 305 by any number of methods, but the choice of method depends strongly on the amount of differential thermal expansion between the top contact plate 330 and the laser die 305. For the case in which the top contact plate 330 is made of a material with a thermal expansion rate similar to that of the laser die 305, a rigid, high-strength bond may be used, such as AuSn solder, or Au diffusion bonding. This has the advantage of tolerating higher operating temperatures, and being relatively free from creep. When the differential thermal expansion between the top contact plate 330 and the laser die 305 is large, e.g. when the top contact plate 330 is pure copper and the laser die 305 is made from GaAs, then a compliant joint must be made. A preferred method of making such a joint is through the use of pure indium solder. In this manner, the excellent thermal and electrical properties of copper may be utilized, as the indium solder will deform to accommodate the expansion of the copper top contact plate 330.

In one embodiment top contact plate 330 is also used to provide additional optical mode control. If the apertures 337 on the to contact plate 330 are made to be of a similar size as the optical mode diameter of an individual emitter, then the top contact plate 330 will also serve to discriminate between optical modes. In other words, top contact plate 330 may have apertures 337 sized to act as an apertures that interact with a portion of the spatial mode to provide beneficial mode discrimination. Typically, this discrimination serves to preferentially select lower order optical modes, but with appropriate patterning, readily understood by those skilled in the art, other, higher order modes can be selected. This type of function works best in VECSEL structures, where the apertures act as intracavity apertures such that discrimination takes place in a resonant cavity.

Electrical connections to the top contact plate 330 and the mount 320 may be handled in several ways. The laser mount 320 can readily be made sufficiently large so that it can serve as a primary current connector. The top contact plate 330, however, is likely to be somewhat fragile, and so it is preferably connected to a more robust part that serves as a primary connector, such as contact member 350. As previously described, a support PCB 340 may also be provided. An electrical connection between top contact plate 330 and contact member 350 may be accomplished by wirebonding or foil-bonding.

In one embodiment, in addition to providing packaging that allows the entire laser array to be uniformly driven, it may be advantageous to provide the ability to drive portions of the array separately from other portions. Examples of such advantages would be pulsed drive. Due to their large optical apertures, VCSELs can be driven at high peak currents without optical damage. This allows for the generation of pulses with high peak power, but normal average power. This is desirable in applications, such as non-linear optical conversion, where peak power is more important than average power. Peak pulse currents can be 5-to-10 times the average current. When driving an array, the peak current can be extremely high, on the order of 500-to-1000A. This level of drive becomes impractical for shorter pulses. An alternative method that avoids the high current level is to rapidly switch a lower, CW drive between elements or segments of the array. In this manner, individual parts of the array see pulses of current that are much higher than normal, CW, operating levels, and the high pulse currents are avoided.

A drive scheme to drive portions of the array separately may be accomplished through several means. In a preferred embodiment the individual emitters are diodes that have at least one contact isolated from each other, for example by etching mesa structures through the epitaxy. The laser submount 390 can then be formed with patterned conductors such that single mesas or groups of mesas are on separate circuits. In a preferred embodiment, the number of segments in the array is equal to the inverse of the duty cycle of the pulser, e.g. an array with 8 segments is pulsed so that each segment is on for 12.5% of the time. In this fashion, the average current pulsed is identical to the CW current.

A consequence of using larger die 305 in an array is that the total physical expansion of the array as it heats up during operation or die attach is greater than that of a smaller die. The generally requires a closer match in coefficients of thermal expansion between the die and the mount, or the use of compliant solders. Given the probability of large thermal loads in an array, a preferred embodiment has a mount with a high thermal conductivity. In a preferred embodiment of the first case, the mount 320 is made of a material with similar coefficient of thermal expansion (CTE) to the laser die, such as CuMo, CuW alloys, or metal diamond composites. In some of these cases, the composition of the material is varied to obtain a precise CTE match. In this embodiment, the joint between the die and the mount can be rigid, and the bond can be made from solders such as AuSn, AuGe, or the bond can be made via Au-diffusion bonding. In the other case, the mount 320 is made of a highly thermally conductive material, and a compliant joint is formed to handle the resultant stress. In one preferred embodiment the mount 320 is formed of copper and the joint is formed from pure indium.

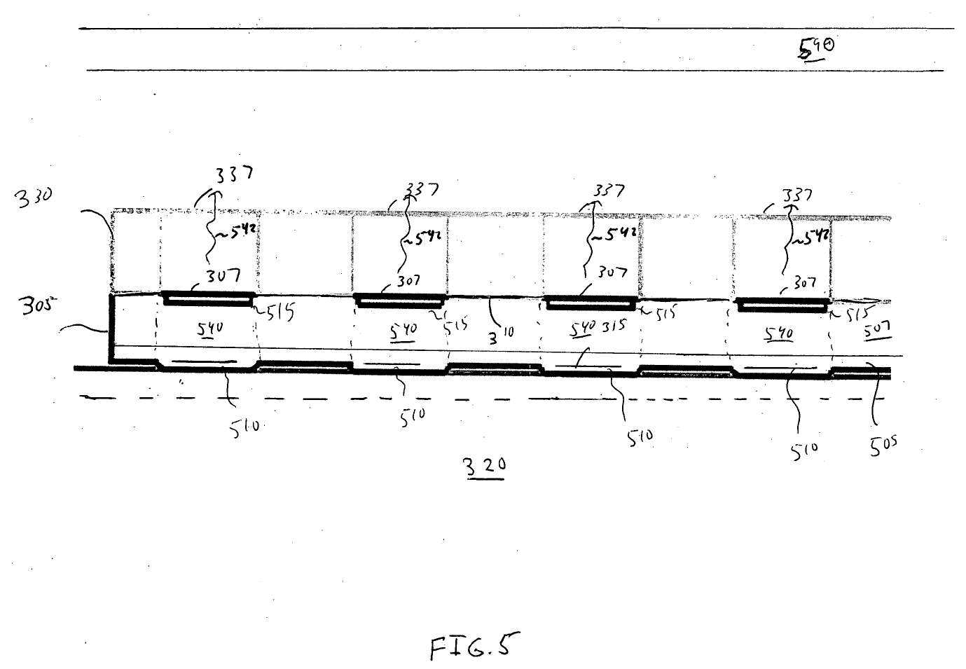

FIG. 5 illustrates in more detail a top contact plate 330 bonded to top surface 310 of laser die 305, which in turn is mounted to mount 320. Laser die 305 includes epitaxial layers 505 grown on a substrate 507. Epitaxial layers 505 may, for example, include quantum well active regions and DBR layers. The epitaxial layers 505 may, for example, include one or more quantum wells disposed between p and n regions of a p-n junction diode. Electrical current is restricted to flow in p-n diode portions of active regions 510 to define individual laser gain elements 540 of the array. For example, mesas and/or other current confinement regions may be formed to constrict the flow of current into a quantum well active region 510 within a gain element 540. The top surface 310 of laser die 305 may also have an annular electrical contact and an anti-reflection layer formed in a region 515 about each individual laser gain element 540 and which includes an aperture 307. Consequently, in one embodiment each individual laser gain element 540 comprises a p-n junction diode to electrically pump an active region 510 with an electrical connection of a first polarity to mount 320 and an electrical connection of a second polarity to top contact plate 330. Each arrow 542 illustrates light generated by an individual laser gain element 540 passing through a respective aperture 337 of top contact plate 330.

In a VECSEL embodiment, an additional reflector 590 is spaced apart from laser die 305. For example, reflector 590 may comprise a volume Bragg grating, an array of, micro-lenses, or other suitable reflective element. In a VECSEL embodiment, each gain element 540 utilizes feedback from a reflector 590 spaced apart from the laser die to define a lasing mode. More generally, however it is contemplated that in some VCSEL embodiments an individual gain element 540 does not require an external reflector to provide optical feedback but instead sufficient optical feedback for lasing is provided by DBR layers and any reflective layers formed on the laser die.

The foregoing description, for purposes of explanation, used specific nomenclature to provide a thorough understanding of the invention. However, it will be apparent to one skilled in the art that specific details are not required in order to practice the invention. Thus, the foregoing descriptions of specific embodiments of the invention are presented for purposes of illustration and description. They are not intended to be exhaustive or to limit the invention to the precise forms disclosed; obviously, many modifications and variations are possible in view of the above teachings. The embodiments were chosen and described in order to best explain the principles of the invention and its practical applications, they thereby enable others skilled in the art to best utilize the invention and various embodiments with various modifications as are suited to the particular use contemplated. It is intended that the following claims and their equivalents define the scope of the invention.

1. A laser array, comprising:
a laser die having a bottom surface attached to a mount, said laser die having an array of vertical cavity surface emitting laser gain elements, said array of vertical cavity surface emitting laser gain elements having an array of surface-emitting apertures disposed on a top surface of said laser die; and
an electrically conductive top contact plate mounted in electrical contact with said top surface of said laser die, said electrically conductive top contact plate formed from at least one electrical conductive sheet patterned to allow light from said surface-emitting apertures to pass through said top-contact plate.

2. The laser array of claim 1, wherein said electrically conductive top contact plate comprises a sheet of metal.

3. The laser array of claim 2, wherein said sheet of conductive metal has a thickness greater than about fifty microns.

4. The laser array of claim 2, wherein said electrically conductive top contact plate comprises a sheet of conductive metal having a thickness of at least about one-hundred microns.

5. The laser array of claim 1, wherein the electrical conductivity and thickness of said electrically conductive top contact plate is selected to achieve a uniformity in voltage drop across said top contact plate such that said surface emitting laser array has a drive current uniformity of better than 1% for a high power mode of operation.

6. The laser array of claim 1, wherein said electrically conductive top plate is attached to the laser die via mechanically compliant solder.

7. The laser array of claim 1, wherein said electrically conductive top plate comprises a material with a thermal expansion rate substantially matched to that of the laser die.

8. The laser array of claim 1, wherein said electrically conductive top plate comprises a stack of plates.

9. The laser array of claim 8, wherein said stack of plates comprises at least two plates having different electrical conductivity.

10. The laser array of claim 8, wherein said stack of plates comprises at least two plates having different rates of thermal expansion.

11. The laser array of claim 1, wherein said top contact plate is patterned with at least one alignment feature.

12. The laser array of claim 11, wherein said laser die is patterned with at least one alignment feature.

13. The laser array of claim 1, wherein said top contact plate has a thermal conductivity and thickness selected such that said top contact plate acts as an auxiliary heat sink for said laser die.

14. The laser array of claim 1, wherein said top contact plate and said laser die are configured such that at least 10% of the heat generated by said laser die is removed via the top contact plate.

15. The laser array of claim 1, wherein the mount has a dissimilar thermal expansion rate and where the resulting stress in managed by the use of a compliant interface layer between the laser die and the mount.

16. The laser array of claim 1, wherein the mount has a substantially identical rate of thermal expansion.

17. The laser array of claim 1, wherein a bottom surface of said laser die has at least one electrically isolated contact per element and the laser die is bonded to a submount of said mount configured to allow single elements or groups of elements to be driven independently of other elements or groups of elements.

18. The laser array of claim 1, wherein the top contact plate has apertures sized to provide discrimination between different transverse optical modes.

19. A laser array, comprising:
a mount;
a laser die having a bottom surface bonded to said mount with a dissimilar thermal expansion rate, and where the resulting stress is managed by the use of a compliant interface layer between the array and the mount, said laser die having an array of vertical cavity surface emitting laser elements, said array of vertical cavity semiconductor elements having an array of surface-emitting apertures disposed on a top surface of said laser die; and
an electrically conductive top contact plate mounted in contact with said top surface of said laser die, said electrically conductive top contact plate formed from at least one electrical conductive sheet patterned to allow optical radiation from said surface-emitting apertures to pass through said top-contact plate.

20. A laser array, comprising:
a laser die having an array of vertical cavity surface emitting laser elements, said array of vertical cavity semiconductor elements having an array of surface-emitting apertures disposed on a top surface of said laser die;
a mount having a rate of thermal expansion substantially equal to said laser die, a bottom surface of said laser die bonded to said mount; and
an electrically conductive top contact plate mounted in contact with said top surface of said laser die, said electrically conductive top contact plate formed from at least one electrical conductive sheet patterned to allow optical radiation from said surface-emitting apertures to pass through said top-contact plate.
